(19) United States
(12) Patent Application Publication
(10) Pub. No.: US 2009/0283125 A1
(43) Pub. Date: Nov. 19, 2009

(54) METHOD AND APPARATUS FOR CHARGING THERMOELECTRICITY USING A PLURALITY OF THERMOELECTRIC GENERATORS

(75) Inventor: Kwang-youn SEO, Suwon-si (KR)

Correspondence Address: STEIN MCEWEN, LLP, 1400 EYE STREET, NW, SUITE 300, WASHINGTON, DC, 20005, US

(73) Assignee: Samsung Electronics Co., Ltd, Suwon-si (KR)

(21) Appl. No.: 12/273,817

(22) Filed: Nov. 19, 2008

(30) Foreign Application Priority Data
May 13, 2008 (KR) 2008-44015

(51) Int. Cl. H01L 35/34; H01L 35/30

(52) U.S. Cl. 136/201; 136/205

(57) ABSTRACT

A method of and an apparatus implementing the method for charging a power supply device by using a plurality of thermoelectric generators includes generating electricity by converting heat generated in each of a plurality of heat sources into electricity, and charging a power supply device by connecting the generated electricity to a charging unit at different times, thereby efficiently charging the power supply device using the electricity generated in the plurality of thermoelectric generators.

### CROSS-REFERENCE TO RELATED APPLICATION

This application claims the benefit of Korean Patent Application No. 2008-44015, filed May 13, 2008 in the Korean Intellectual Property Office, the disclosure of which is incorporated herein by reference.

### BACKGROUND OF THE INVENTION

1. Field of the Invention

Aspects of the present invention relate to a method of and apparatus for charging a power supply device by using a thermoelectric generator, and more particularly, to a method and apparatus for efficiently charging a power supply device using electricity generated by a plurality of thermoelectric generators.

2. Description of the Related Art

A physical phenomenon in which the flow of heat and electric current influence each other is referred to as a thermoelectric effect. The Seebeck effect and the Peltier effect are examples of the thermoelectric effect. The thermoelectric effect occurs in a circuit in which metals or semiconductors having different thermoelectric properties are bonded. Also, the conversion of heat energy and electric energy using the circuit is called thermoelectric conversion. According to the Seebeck effect, heat energy is converted into electric energy, or according to the Peltier effect, electric energy is converted into heat energy.

By using the thermoelectric conversion, electricity can be produced from heat flux, or heat absorption or heat radiation can be generated using a current. The thermoelectric conversion is direct conversion, and thus an excessive amount of waste is not generated during energy conversion. Also, since there is no need to use a driving unit like a motor or a turbine, maintenance and repair of a thermoelectric conversion based device is convenient. Accordingly, the thermoelectric conversion is being highlighted as a high efficiency energy technology.

A module performing thermoelectric conversion using the Seebeck effect is called a thermoelectric generator (TEG). In the TEG, when a side of the TEG is heated and the other side is cooled, heat energy flows from the heated side to the cooled side, and the TEG converts the energy to generate a current. For example, when a side of the TEG is attached to a central processing unit (CPU) and the other side is attached to a heat sink such as a cooling fan, a flow of heat energy from the CPU to the heat sink is generated, and the TEG converts the heat energy into electricity, thereby generating a current.

### SUMMARY OF THE INVENTION

Aspects of the present invention provide an apparatus for and method of efficiently charging a power supply device using electricity generated in a plurality of thermoelectric generators.

Aspects of the present invention provide a computer readable medium having a computer program for executing the above method.

According to an aspect of the present invention, there is a thermoelectricity charging apparatus comprising: a plurality of thermoelectric generators generating electricity by converting heat generated in a plurality of heat sources into electricity; a selection unit transmitting electricity generated in the plurality of the thermoelectric generators to a charging unit at different times; and a charging unit charging a power supply device using the electricity generated in the plurality of the thermoelectric generators and according to the transmission by the selection unit.

According to an aspect of the present invention, the selection unit may comprise: an electricity storing unit individually storing electricity generated in each of the plurality of the thermoelectric generators; a comparing unit determining whether the electricity respectively stored in the electricity storing unit is of a predetermined voltage or greater; and a switching unit transmitting the electricity of the predetermined voltage or greater to the charging unit at different times, based on the result of the comparison of the comparing unit.

According to an aspect of the present invention, the comparing unit may comprise a plurality of comparators determining whether the voltage of the electricity stored in the electricity storing units is of the predetermined voltage or greater, and outputting a plurality of control signals according to the determination result, and the switching unit comprises a plurality of metal-oxide-semiconductor (MOS) transistors connecting electricity of the predetermined voltage or greater from among the electricity stored in the electricity storing unit to the charging unit at different times according to the plurality of control signals.

According to an aspect of the present invention, the thermoelectric charging apparatus may further comprise an interleaving control unit generating a plurality of interleaving signals that control the switching unit such that the electricity of the predetermined voltage or greater is transmitted to the charging unit at different times.

According to another aspect of the present invention, there is provided a method of charging thermoelectricity, the method comprising: generating electricity by converting heat generated in a plurality of heat sources into electricity; controlling the order of charging so as to charge a power supply device using the generated electricity at different times; and charging a predetermined power supply device according to the order of charging.

According to an aspect of the present invention, the controlling of the order of charging may comprise: individually storing electricity in each of the heat sources; determining whether the stored electricity is of a predetermined voltage or greater; and arranging the order of charging so as to charge at different times a power supply device using the electricity of the predetermined voltage or greater, based on the determination result.

According to an aspect of the present invention, the determining may comprise determining whether the voltage of the electricity individually stored in the electricity storing unit is of a predetermined voltage or greater, and generating a plurality of control signals based on the determination result, and the arranging of the order of charging may comprise arranging the order of charging such that a power supply device is charged at different times using the electricity of the predetermined voltage or greater, based on the plurality of control signals.

According to another aspect of the present invention, there is provided a computer readable recording medium having embodied thereon a computer program for executing the above-described method of charging thermoelectricity.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a schematic view of a thermoelectricity charging apparatus according to an embodiment of the present invention;

FIG. 2 is a schematic view of a thermoelectricity charging apparatus according to an embodiment of the present invention;

FIG. 3 is a schematic view of a thermoelectricity charging apparatus according to an embodiment of the present invention;

FIG. 4 illustrates interleaving signals and voltages of stored electricity, according to an embodiment of the present invention; and

FIG. 5 is a flowchart illustrating a method of charging a power supply device using thermoelectricity according to an embodiment of the present invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

Two or more heating devices such as a CPU or a graphic processing unit (GPU) may be disposed in electronic devices like a desktop computer, and when the above-described thermoelectricity generating (TEG) unit is attached to such heating devices, the heat generated in the desktop computer can be converted into electricity to be used as new power. An example of such a combination of TEG units is found in U.S. patent application Ser. No. 12/196,789, filed Aug. 22, 2008, the disclosure of which is incorporated by reference. However, the electricity generated by converting heat generated in different heating devices has different powers, and thus cannot be used at the same time to charge a power supply device. Accordingly, there is a need for an apparatus and method of charging a power supply device by efficiently controlling the electricity generated in a plurality of TEG units.

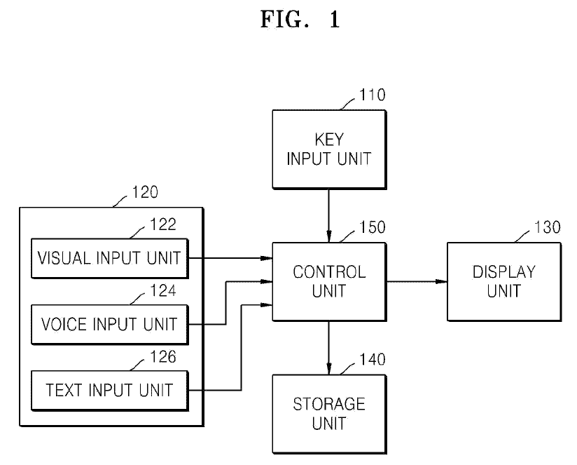

FIG. 1 is a schematic view of a thermoelectricity charging apparatus 100 according to an embodiment of the present invention. Referring to FIG. 1, the thermoelectricity charging apparatus 100 includes TEG units 110, 120, and 130, a selection unit 140, a charging unit 150, a control unit 160, and a power supply device 170.

The TEG units 110, 120, and 130 convert heat, which is generated in a plurality of heat sources (not shown), into electricity. As described in the description of the conventional art, heat energy generated in a plurality of heat sources is converted into electric energy according to the Seebeck effect, thereby generating a current. For example, a desktop computer includes at least two chips generating heat energy, such as a CPU and a GPU. One of the TEG units 110, 120, and 130 could be attached to the CPU, another of the TEG units 110, 120, and 130 could be attached to the GPU, and another of the TEG units 110, 120, and 130 could be attached to another chip in the computer. As such, a plurality of TEG units 110, 120, and 130 perform thermoelectric conversion are attached to the chips to convert heat energy into electric energy. However, it is understood that the apparatus 100 can be used in other devices, such as portable electronic media players, vehicles, servers, and other portable or non-portable devices which generate heat using multiple internal devices which needs to be dissipated.

The selection unit 140 connects the electricity generated in each of the plurality of the thermoelectricity generating units 110, 120, and 130 to the charging unit 150 at different times. The plurality of the thermoelectricity generating units 110, 120, and 130 illustrated in FIG. 1 are connected to corresponding heat sources (not shown) to generate electricity. The amounts of heat energy generated in the plurality of heat sources (e.g., in a plurality of chips) are different from one another, and thus the electricity generated in each of the thermoelectricity generating units 110, 120, and 130 has also different powers. While shown with three thermoelectricity generating units 110, 120, and 130, it is understood that other numbers of thermoelectricity generating units can be used. Accordingly, if the electricity generated in various thermoelectricity generating units 110, 120, 130 is used to charge a power supply device at the same time, the efficiency of charging may decrease due to the interference between electricity of different powers. To prevent this, the electricity generated in each of the thermoelectric generating units is transmitted to the charging unit 150 at different times. However, while described as different, it is understood that the powers generated in two or more of the thermoelectric generating units 110, 120, 130 can be the same.

While not required in all aspects, the selection unit 140 may preferably transmit electricity of a predetermined voltage or greater, from among the electricity generated in the plurality of TEG units 110, 120, and 130, selectively to the charging unit 150. In other words, from among the electricity generated in the plurality of TEG units 110, 120, and 130, electricity of a predetermined voltage or greater is transmitted to the charging unit 150 at different times. A predetermined voltage refers to a voltage required for the charging unit 150 to charge the power supply device 170. However, it is understood that other criterion can be used to determine which to transmit.

The charging unit 150 charges the power supply device 170 using the electricity generated in the plurality of the thermoelectricity generating units 110, 120, and 130 which are connected to the charging unit 150 by the selection unit 140. The electricity generated in the plurality of the TEG units 110, 120, and 130 at a predetermined voltage or greater is used at different times to charge the power supply device 170. The power supply device 170 may be a device such as a secondary battery which stores chemical energy, but is not restricted thereto.

In order to control the discharge of the TEG units 110, 120, and 130 when plural TEG units 110, 120, and 130 have stored voltage at or above the predetermined voltage, the control unit 160 coordinates the discharge. By way of example, the control unit 160 generates a plurality of interleaving signals to control the selection unit 140 so that the selection unit 140 transmits the electricity generated in the plurality of the thermoelectricity generating units 110, 120, and 130 to the charging unit 150 at different times. The control unit 160 generates a plurality of interleaving signals by time division to control the selection unit 140 so that the electricity generated in the plurality of the thermoelectricity generating units 110, 120, and 130 is transmitted to the charging unit 150 not at the same time but at different times. While not limited thereto, the control unit 160 can be a computer and/or one or more processors.

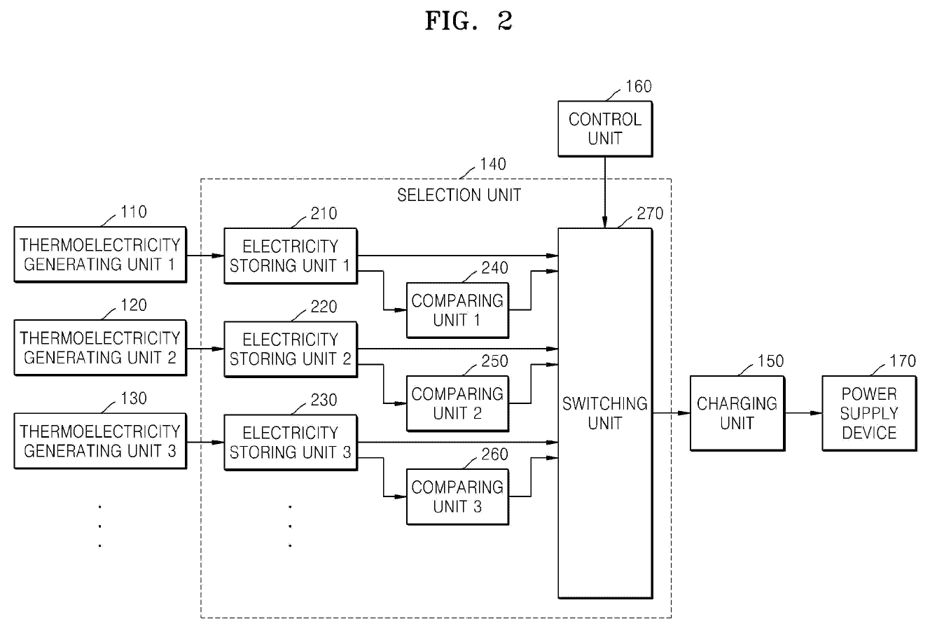

FIG. 2 is a schematic view of a thermoelectricity charging apparatus according to an embodiment of the present invention. FIG. 2 illustrates the selection unit 140 in detail. Referring to FIG. 2, the selection unit 140 includes a plurality of electricity storing units 210, 220, and 230, a plurality of comparing units 240, 250, and 260, and a switching unit 270.

The electricity storing unit 210 stores electricity generated by the thermoelectricity generating unit 110; the electricity storing unit 220 stores electricity generated by the thermoelectricity generating unit 120; and the electricity storing unit 230 stores electricity generated by the thermoelectricity generating unit 130. Here, electricity generated in the thermoelectricity generating unit 1 110 will be taken as an example. The selection unit 140 does not transmit the electricity generated in the thermoelectricity generating unit 1 110 to the charging unit 150 directly, but stores the electricity first in an electricity storing unit 1 210 and then transmits the electricity to the charging unit 150 through the switching unit 270 under the control of the control unit 160. While not restricted thereto, the electricity storing units 210, 220, 230 can be capacitors, secondary batteries or other energy storage devices.

Electricity generated by converting heat energy into electricity in the thermoelectricity generating unit 1 110 may be unstable. If this unstable electricity is transmitted directly to the charging unit 150 and used in charging, the charging efficiency may be degraded. For example, when converting heat energy generated in a CPU into electric energy using the thermoelectricity generating unit 1 110, the electricity generated by the thermoelectricity generating unit 1 110 is large when the CPU is operated since there is a great deal of heat energy when the CPU is operated. In contrast, when the CPU is not operated, the electricity generated the thermoelectricity generating unit 1 110 is small since there is less heat generated when the CPU is not operated. Thus, the generated electricity from the thermoelectricity generating unit 1 110 has different powers depending on when the CPU is operated. Accordingly, the electricity with varying powers is not directly transmitted to the charging unit 150 through the switching unit 270. Instead, the energy is stored first in the electricity storing unit 1 210, and then transmitted to the charging unit 150 through the switching unit 270.

A comparing unit 1 240 determines whether the electricity stored in the electricity storing unit 1 210 is of a predetermined voltage or greater, and transmits a control signal according to the determination, to the switching unit 270. The control signal is for controlling the switching unit 270 so that only electricity of a predetermined voltage or greater is transmitted to the charging unit 150. The switching unit 270 transmits the electricity stored in the electricity storing unit 1 210 to the charging unit 150 based on the control signal generated in the comparing unit 1 240, when the electricity stored in the electricity storing unit 1 210 is of a predetermined voltage or greater. When the electricity stored in the electricity storing unit 1 210 is discharged and is below the predetermined voltage, the comparing unit 1 240 transmits again a control signal to the switching unit 270, and the switching unit 270 disconnects the electricity storing unit 1 210 and the charging unit 150 so that the electricity generated in the thermoelectricity generating unit 1 110 is stored again in the electricity storing unit 1 210.

Electricity generated in thermoelectricity generating units 2, 3 120, 130 is also stored in the corresponding electricity storing units 2, 3 220, 230, respectively, and transmitted to the charging unit 150 through the switching unit 270. Comparing units 2 and 3 (250, 260) respectively determine whether the electricity stored in the electricity storing units 2 and 3 (220, 230) is of a predetermined voltage or greater to transmit control signals to the switching unit 270.

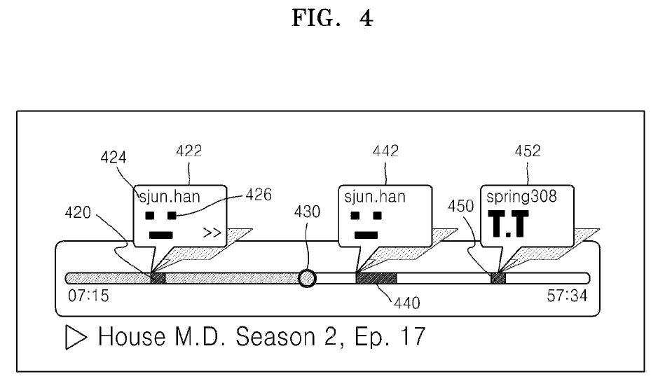

The switching unit 270 connects the electricity to the charging unit 150 at different times as described above, when all or plural of the electricity stored in the electricity storing units 1, 2, and 3 210, 220, and 230 are storing a predetermined voltage or greater. The control unit 160 generates interleaving signals to the switching unit 270 so that the electricity stored in the electricity storing units 1, 2, and 3 210, 220, and 230 is transmitted to the charging unit 150 at different times. The switching unit 270 time-divides only the electricity stored at a predetermined voltage or greater based on the plurality of control signals generated in the plurality of comparing units 240, 250, and 260 and interleaving signals generated in the control unit 160, to transmit it to the charging unit 150 at different times. The interleaving signals will be described in detail later with reference to FIG. 4.

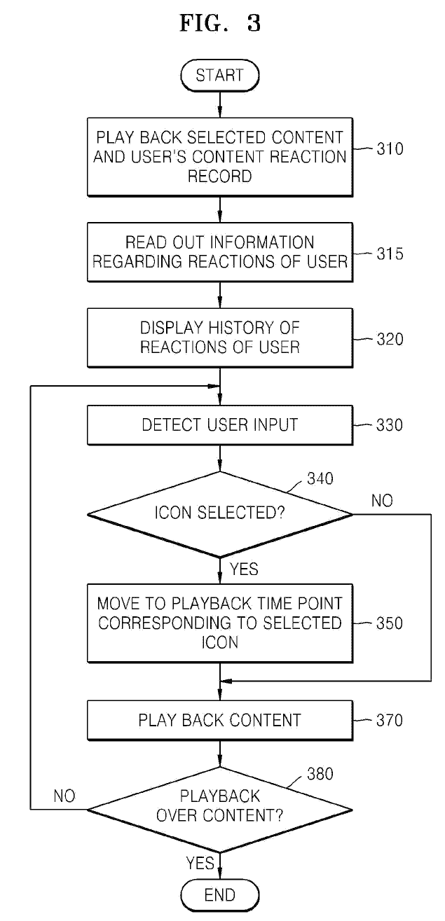

FIG. 3 is a schematic view of a thermoelectricity charging apparatus according to another embodiment of the present invention. FIG. 3 illustrates in detail an example of the electricity storing units 210, 220, and 230, the comparing units 240, 250, and 260, and the switching unit 270 illustrated in FIG. 2.

The electricity storing units 210, 220, and 230 store electricity generated in the thermoelectricity generating units 110, 120, and 130 individually in corresponding capacitors C₁, C₂, and C₃. By way of example, the electricity storing unit 1 210 stores electricity generated in the thermoelectricity generating unit 1 110 in the capacitor C₁. The electricity storing unit 1 210 further includes a resistor R₁, where a resistance of the resistor R₁ and a capacitance of the capacitor C₁ are set up such that a maximum power can be transmitted to the charging unit 150. In other words, the resistance of resistor R₁ is set to be equal to the internal resistance of the thermoelectricity generating unit 1 110 so that a maximum power is transmitted to the charging unit 1 210, and the capacitance is set such that discharging or charging of the capacitor C₁ is completed within an appropriate period of time in consideration of a logic high time T_{H} and a logic low time T_{L} of an interleaved signal, which will be described later with reference to FIG. 4.

In the same manner, resistances of resistors R₂ and R₃ and capacitances of the capacitors C₂ and C₃ of the electricity storing units 2 and 3 220 and 230 are determined. Electric energy and internal resistance generated in the thermoelectricity generating units 110, 120, and 130 are different from one another, and thus different resistances and capacitances can be determined for each of the electricity storing units 210, 220, and 230. However, it is understood that the resistances and capacitances can be the same in other aspects and need not each be different.

The comparing units 240, 250, and 260 compare voltages of nodes 1, 2, and 3 (that is, voltages stored in each of the electricity storing units 210, 220, and 230) with a reference voltage, to determine whether the voltages of the nodes 1, 2, and 3 are above the reference voltage Ref. As described above with reference to the comparing units 240, 250, and 260 of FIG. 2, the switching unit 270 transmits only electricity of a predetermined voltage or above to the charging unit 150. To this end, the comparing units 240, 250, and 260 respectively include comparators 242, 252, and 262. The comparators 242, 252, 262 compare the corresponding voltages stored in the electricity storing units 210, 220, and 230 with a reference voltage Ref. As shown, the switching unit 270 includes switching unit 1 272, switching unit 2 274, and switching unit 3 276. While shown using circuitry, it is understood that one or all of the switching units 272, 274, 276 can be implemented using software and/or firmware for use with a processor or computer, and may be combined with the control unit 160 where the control unit 160 is implemented using software and/or firmware executed using a processor and/or computer according to aspects of the invention.

For example, when the voltage of the node 1 is higher than the reference voltage Ref, the comparator 1 242 applies a voltage V_drv of 12 V to the switching unit 1 272. When the voltage of the node 1 is lower than the reference voltage Ref, the comparator 1 242 applies 0 V to the switching unit 1 272. A voltage applied by the comparator 1 242 to the switching unit 272 is used as a control signal for the switching unit 1 272 to selectively transfer the voltage of the electricity storing unit 1 210 to the charging unit 150. A resistor R_{C} is for minutely adjusting the voltage applied to a positive terminal of the comparator 1 242, and may be omitted. For example, by increasing the resistance R_{C}, a voltage applied to a positive terminal of the comparator 1 242 can be reduced.

In the same manner, the comparator 2 252 and the comparator 3 262 compare the voltages of the corresponding nodes 2 and 3 with the reference voltage Ref to transmit predetermined control signals to the switching units 2 and 3, 274 and 276.

The switching units 272, 274, and 276 selectively connect voltages the nodes 1, 2, and 3 to the charging unit 150. While not required in all aspects, a metal-oxide-semiconductor (MOS) transistor, and preferably a metal oxide semiconductor field-effect transistor (MOSFET), is used to selectively connect voltages stored in the electricity storing units 210, 220, and 230 to the charging unit 150. However, it is understood that other switching devices can be used to selectively apply the voltages.

Regarding the switching unit 1 272, a voltage of the comparator 1 242 is applied to a gate G of a MOSFET. In other words, when the voltage of the node 1 is higher than the reference voltage Ref, and the comparator 1 242 applies a voltage of 12 V to the switching unit 1 272, then a voltage of 12 V is applied to the gate G of the MOSFET. Accordingly, a source S and a drain D are connected to each other and the voltage stored in the electricity storing unit 1 210 is transmitted to the charging unit 150. However, in the contrast, if the voltage of the node 1 is lower than a reference voltage Ref, and the comparator 1 242 applies 0 V to the switching unit 1 272, 0 V is also applied to the gate G of the MOSFET, the connection between the source S and the drain D is disconnected and the voltage of the electricity storing unit 1 210 is not transmitted to the charging unit 150.

Resistors R_{X} and R_{Y} present in each of the switching units 272, 274, 276 are to prevent damping, and are not related to the switching of the MOSFET. Capacitors C_{Z1}, C_{Z2}, and C_{Z3} are electric condensers to exactly adjust switching timings of the switching units 272, 274, and 276. Also, diodes in each of the switching units block reflow of a current in a charging unit or other electric storing units. However, it is understood that other combinations of electrical elements can be used to prevent damping, adjust switching timings, and/or block reflow in addition to or instead of the shown elements.

While the switching unit 1 272 performs switching, electricity stored in the electricity storing units 210, 220, and 230 may be controlled by the control unit 160 so that the electricity is transmitted to the charging unit 150 at different times. In other words, the switching unit 1 272 can also adjust switching timing not only by control signals applied by the comparator 1 242 but also by interleaving signals generated by the control unit 160 in order to control the timing of the transmission of electricity when plural electricity storing units 210, 220, and 230 have energy at or above the reference voltage Ref.

FIG. 4 illustrates interleaving signals and voltages of stored electricity, according to an embodiment of the present invention. Referring to FIGS. 3 and 4, a plurality of interleaving signals applied by the control unit 160 to the switching units 272, 274, and 276 are a plurality of pulse signals having a first logic state at different times. A first logic state refers to a logic high state, and a second logic state refers to a logic low state. However, in other embodiments of the present invention, the same effect can be obtained while having the opposite logic state. The voltage of the node 1 is decreased only when an interleaving signal 1 transmitted by the control unit 160 to the switching unit 1 272 is in a logic high state as electricity stored in the electricity storing unit 1 210 is transmitted to the charging unit 150. Even when a control signal applied by the comparator 1 242 to the switching unit 1 272 is 12 V, if the interleaving signal 1 applied by the control unit 160 to the switching unit 1 272 is at a logic low, a voltage of logic low is applied to the gate G of a MOSFET, and thus a current does not flow from the source S to the drain D. In other words, if a control signal that is applied by the comparator 1 242 to the switching unit 1 272 is 12 V, and an interleaving signal 1 applied by the control unit 160 to the switching unit 1 272 is a logic high, a logic high voltage is applied to the gate G of a MOSFET, and thus a current can flow from the source S to the drain D.

In short, even when the voltage of the electricity stored in the electricity storing unit 1 210 is of the predetermined voltage or greater, the electricity stored in the electricity storing unit 1 210 is transmitted to the electricity storing unit 150 only for a time T_{H} during which the interleaving signal 1 is a logic high, and the electricity stored in the electricity storing unit 1 210 is not transmitted to the charging unit 150 for a time T_{L} during which the interleaving signal 1 is a logic low. The capacitor C₁ of the electricity storing unit 1 210 is determined considering T_{H} and T_{L}, and electricity of the electricity storing unit 1 210 is discharged within T_{H}, and a voltage V_{TH} is generated to be determined to be sufficiently stored within T_{L}. Accordingly, since the electricity of the capacitor C₁ is repeatedly stored or discharged, the voltage of the node 1 is repeatedly raised or declined according to T_{H} and T_{L}, as illustrated in FIG. 4.

In the same manner, an interleaving signal 2 is transmitted to the switching unit 2 274, and an interleaving signal 3 is transmitted to the switching unit 3 276. The interleaving signal 2 and the interleaving signal 3 are logic high signals at different times, as illustrated in FIG. 4, and the voltages of the node 2 and the node 3 which are modified according to the interleaving signals are as illustrated in FIG. 4.

Also, a predetermined delay time is set between times in which the interleaving signals are logic highs. For example, by setting a predetermined delay time between a time in which an interleaving signal 1 is a logic high and a time in which an interleaving signal 2 is a logic high, the electricity stored in the electricity storing unit 1 210 and the electricity stored in the electricity storing unit 2 220 are prevented from being transmitted to the charging unit 150 at the same time.

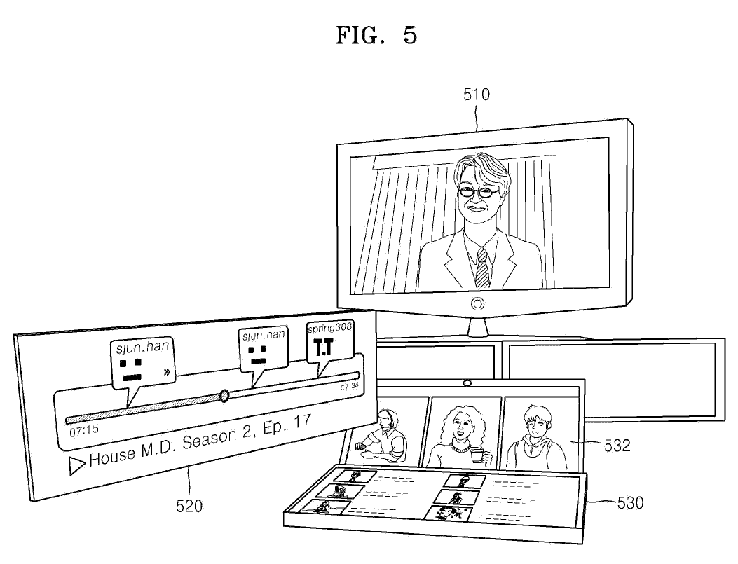

FIG. 5 is a flowchart illustrating a method of charging thermoelectricity according to an embodiment of the present invention. Referring to FIG. 5, in operation 510, a thermoelectricity charging apparatus converts heat energy generated in a plurality of heat sources into electricity. By using a plurality of thermoelectric generators (TEG) which convert heat energy into electric energy using the Seebeck effect, heat energy generated in a plurality of heat sources is converted to electricity.

In operation 520, the thermoelectricity charging apparatus controls the order of charging so as to charge a power supply device using the generated electricity at different times. While not required in all aspects, the electricity generated in a plurality of heat sources is of different powers, and the power supply device is not charged with this electricity at the same time but at different times.

To this end, the electricity generated in a plurality of heat sources is stored individually in a plurality of electricity storing units, and it is determined whether the stored electricity is of a predetermined voltage or greater using a comparator. Then, the order of charging is arranged to charge a power supply device using the electricity of different powers at different times. As illustrated in the example of FIGS. 3 and 4, the order of charging is arranged to charge a power supply device using the electricity stored in the order of the thermoelectricity generating unit 1 110, the thermoelectricity generating unit 2 120, and the thermoelectricity generating unit 3 130. The order of charging can be controlled so as to use the electricity of a predetermined voltage or greater at different times, by controlling a MOS transistor using a plurality of control signals generated by a plurality of comparators which determine whether the stored electricity is at a predetermined voltage or greater and a plurality of interleaving signals having a first logic state at different times for controlling the order of charging. As described above, the MOS transistor may preferably be a MOSFET, but is not limited thereto.

In operation 530, the thermoelectricity charging apparatus charges a predetermined power supply device according to the order of charging that is controlled in operation 520. The power supply device is charged using the electricity generated by converting heat energy in a plurality of thermoelectricity generating units at different times.

According to aspects of the present invention, a power supply device can be efficiently charged by sequentially using electricity of different powers generated in a plurality of thermoelectric generators without electricity leakage.

While the present invention has been particularly shown and described with reference to exemplary embodiments thereof, it will be understood by those skilled in the art that various changes in form and detains may be therein without departing from the spirit and scope of the invention as defined by the appended claims. The exemplary embodiments should be considered in a descriptive sense only, and not for purpose of limitation. Therefore, the scope of the invention is defined not by the detailed description of the invention but by the appended claims, and all differences within the scope will be construed as being included in the present invention. The invention can also be embodied as computer readable codes on a computer readable recording medium readable by a computer, processor and/or controller. The computer readable recording medium is any data storage device that can store data which can be thereafter read by a computer system. Examples of the computer readable recording medium include read-only memory (ROM), random-access memory (RAM), CD-ROMs, magnetic tapes, magnetic media, floppy disks, and optical data storage devices. The computer readable recording medium can also be distributed over network coupled computer systems so that the computer readable code is stored and executed in a distributed fashion.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A thermoelectricity charging apparatus for use with heat sources comprising:
thermoelectric generators to convert heat generated by the corresponding heat sources into electricity;
a selection unit to selectively transmit the generated electricity to be stored at corresponding different times; and
a charging unit to charge a power supply device using the selectively transmitted electricity according to the transmission by the selection unit.

2. The thermoelectric charging apparatus of claim 1, wherein the selection unit comprises:
electricity storing units to individually store the electricity generated in the corresponding thermoelectric generators;
a comparing unit to determine whether the electricity respectively stored in each of the corresponding electricity storing units is of a predetermined voltage or greater; and
a switching unit to selectively transmit the electricity from determined ones of the electricity storing units to the charging unit at corresponding different times when a result of the comparison of the comparing unit indicates that the electricity storing unit stores electricity of the predetermined voltage or greater and does not transmit the electricity from other ones of the electricity storing units when the result of the comparison of the comparing unit indicates that the electricity storing unit stores electricity which is less than the predetermined voltage.

3. The thermoelectric charging apparatus of claim 2, wherein the comparing unit comprises a plurality of comparators to determine whether, for each of the electricity storing units, the voltage of the electricity stored in the electricity storing unit is of the predetermined voltage or greater, and to output a control signal for each electricity storing unit according to the determination result, and
the switching unit comprises a plurality of metal-oxide-semiconductor (MOS) transistors to connect electricity determined to be of the predetermined voltage or greater from among the electricity stored in the electricity storing units to the charging unit at corresponding different times according to the plurality of control signals.

4. The thermoelectric charging apparatus of claim 3, wherein the MOS transistor comprises a metal oxide semiconductor field-effect transistor (MOSFET).

5. The thermoelectric charging apparatus of claim 3, further comprising an interleaving control unit generating interleaving signals that control the switching unit such that the electricity of the predetermined voltage or greater is transmitted from the corresponding electricity storing units to the charging unit at corresponding different times.

6. The thermoelectric charging apparatus of claim 5, wherein the interleaving control unit generates the plurality of interleaving signals having a first logic state at the corresponding different times, and the switching unit transmits the electricity from the one of electricity storing unit to the charging unit when the signal is of the first logic state and the electricity stored in the electricity storing unit is of the predetermined voltage or greater.

7. The thermoelectric charging apparatus of claim 6, wherein the switching unit controls the MOS transistor so that the electricity determined to be of the predetermined voltage or greater is transmitted to the charging unit at different times, based on the plurality of control signals and the plurality of interleaving signals.

8. A method of charging thermoelectricity, the method comprising:
converting heat generated in a plurality of heat sources into electricity;
controlling an order of charging so as to charge a power supply device using the generated electricity at corresponding different times; and
charging the power supply device according to the controlled order of charging.

9. The method of claim 8, wherein the controlling the order of charging comprises:
individually storing electricity generated by each of the heat sources;
determining whether the individually stored electricity is of a predetermined voltage or greater; and
arranging the order of charging so as to charge at corresponding different times the power supply device using the individually stored electricity determined to be the predetermined voltage or greater and not charging the power supply device when the individually stored energy is determined to be less than the predetermined voltage, based on the determination result.

10. The method of claim 9, wherein:
the determining comprises determining whether the voltage of the individually stored electricity is of the predetermined voltage or greater, and generating a plurality of control signals based on the determination result, and
the arranging the order of charging comprises arranging the order of charging such that the power supply device is charged at corresponding different times using the electricity determined to be of the predetermined voltage or greater, based on the plurality of control signals.

11. The method of claim 10, wherein the order of charging is arranged based on the plurality of control signals and a plurality of interleaving signals, the interleaving signals control the transmission such that a plurality of the individually stored electricity determined to be of the predetermined voltage or greater are transmitted to the charging unit at different times.

12. The method of claim 11, wherein the plurality of interleaving signals have a first logic state at different times.

13. The thermoelectric charging apparatus of claim 1, wherein the thermoelectric charging apparatus is disposed in a computer, and ones of the heat elements comprise corresponding processors to which the corresponding thermoelectric generators are connected in order to generate the electricity using heat generated by the processors.

14. A thermoelectricity charging apparatus for use with heat sources connected to corresponding thermoelectric generators used to convert heat generated in the corresponding heat sources into electricity, the apparatus comprising:
a selection system to selectively transmit the generated electricity to be stored such that electricity from one of the thermoelectric generators is transmitted at a different time than the electricity from another one of the thermoelectric generators; and
a charging unit to charge a power supply device using the selectively transmitted electricity received from the selection system.

15. The thermoelectric charging apparatus of claim 14, wherein the selection system comprises:
a selection unit which determines which of the thermoelectric generators has generated electricity of at least a predetermined voltage; and
a control unit which coordinates a transmission of the electricity generated by ones of the thermoelectric generators determined to have generated electricity of at least the predetermined voltage to be at different times, and prevents the transmission from other ones of the thermoelectric generators determined to have generated electricity which is below the predetermined voltage.

16. The thermoelectric charging apparatus of claim 15, further comprising, for each thermoelectric generator, a storage unit which stores the generated electricity generated by the thermoelectric generator, and a comparison unit which indicates to the selection unit when the storage unit has stored electricity which is at least the predetermined voltage.

17. The thermoelectric charging apparatus of claim 16, wherein at least one of the storage units comprises a capacitor which stores the electricity.

18. The thermoelectric charging apparatus of claim 16, wherein at least one of the comparison units comprises a comparator which compares a reference voltage with a voltage of the electricity stored in the corresponding storage unit, sends a signal indicating when the stored electricity is at least the predetermined voltage, and sends another signal indicating when the stored electricity is less than the predetermined voltage.

19. The thermoelectric charging apparatus of claim 15, wherein the control unit determines a number indicating how many of the thermoelectric generators have generated electricity of at least the predetermined voltage, creates an interleaving signal according to the determined number, and uses the created interleaving signal to selectively allow the generated electricity to be transmitted at the different times.

20. The thermoelectric charging apparatus of claim 14, wherein the selection system detects which of the thermoelectric generators has generated electricity of at least a predetermined voltage, and selectively transmits the generated electricity only from the thermoelectric generators having generated the electricity of at least the predetermined voltage.

21. A method of charging thermoelectricity, the method comprising:
using electricity generated by thermoelectric generators from heat generated from a plurality of heat sources, determining an order of charging so as to charge a power supply device using the generated electricity such that electricity generated using the heat from a first one of the heat sources is to be stored at a different time than electricity generated using the heat from a second of the heat sources; and
controlling a transmission of electricity to charge the power supply device according to the determined order of charging.

22. The method of claim 21, wherein
the determining the order of charging comprises determining which of the thermoelectric generators has generated electricity of at least a predetermined voltage; and
the controlling the transmission comprises coordinating a transmission of the electricity generated by ones of the thermoelectric generators determined to have generated electricity of at least the predetermined voltage at different times, and preventing the transmission from other ones of the thermoelectric generators determined to have generated electricity which is below the predetermined voltage.

23. The method of claim 22, further comprising, for each thermoelectric generator, storing in a storage unit the generated electricity generated by the thermoelectric generator, and sending a signal from a comparison unit which sends the signal when the storage unit has stored electricity which is at least the predetermined voltage, wherein the determining which of the thermoelectric generators has generated the electricity comprises detecting the signal.

24. The method of claim 21, wherein the determining the order comprises:
determining a number indicating how many of the thermoelectric generators have generated electricity of at least a predetermined voltage,
creating an interleaving signal according to the determined number, and
using the created interleaving signal to determine the order of charging to selectively allow the generated electricity to be transmitted at the different times.

25. A computer readable recording medium having embodied thereon a computer program for executing the method of claim 21 using one or more computers.
